(19) United States
(12) Patent Application Publication
(10) Pub. No.: US 2025/0391733 A1
(43) Pub. Date: Dec. 25, 2025

(54) SEMICONDUCTOR DEVICE

(71) Applicant: FUJI ELECTRIC CO., LTD., Kawasaki-shi (JP)

(72) Inventor: Naoyuki KANAI, Matsumoto-city (JP)

(73) Assignee: FUJI ELECTRIC CO., LTD., Kawasaki-shi (JP)

(21) Appl. No.: 19/193,623

(22) Filed: Apr. 29, 2025

(30) Foreign Application Priority Data
Jun. 21, 2024 (JP) 2024-100602

(51) Int. Cl. H01L 23/373; H01L 23/00; H01L 23/29; H01L 23/498; H01L 23/60; H01L 23/62

(52) U.S. Cl. CPC H01L 23/3737; H01L 23/295; H01L 23/3735; H01L 23/60; H01L 23/62; H01L 23/49811; H01L 24/48; H01L 2224/48229; H01L 2924/12032; H01L 2924/13055

(57) ABSTRACT

The present invention relates to a semiconductor device including a semiconductor module 10 that includes a laminated substrate 2 in which conductive plates 21a, 21b, 23 are arranged on both sides of an insulating substrate 22 having relative permittivity ε₀, a semiconductor element 1 mounted on the laminated substrate 2, and an encapsulant 6 that seals and insulates the laminated substrate 2 and the semiconductor element 1; an adhesive layer 11 containing an epoxy resin and a filler that includes first particles having relative permittivity ε₁ exceeding 10; and a cooling apparatus 12 disposed on the semiconductor module via the adhesive layer, wherein ε₀<ε₁.

### CROSS-REFERENCE TO RELATED APPLICATION

This application claims priority from Japanese Patent Application No. 2024-100602, filed on Jun. 21, 2024, which is incorporated herein by reference in its entirety.

### FIELD OF THE INVENTION

### Background of the Invention

The present invention relates to a semiconductor device. More particularly, the present invention relates to a semiconductor device with excellent discharge-resistance property (voltage-resistance property) and high reliability.

### Description of Related Art

Power semiconductor modules are widely used in fields demanding efficient power conversion. Examples include renewable energy sectors such as solar power generation and wind power generation, which have attracted significant attention in recent years, automotive sectors such as hybrid vehicles and electric vehicles, and railway sectors such as rolling stock. In these power semiconductor modules, a semiconductor element and a diode are built-in; the semiconductor element is sealed and insulated by a thermosetting resin such as silicone gel or epoxy resin. The power semiconductor module is then installed on a cooling apparatus via a thermal compound and is utilized as a power semiconductor device.

Conventionally, a semiconductor device is known that includes: a semiconductor module having a laminated substrate on which a semiconductor element is mounted and an encapsulant; and a cooling apparatus disposed in the semiconductor module, wherein the semiconductor module is placed on the cooling apparatus via a thermal compound that contains a filler having high-dielectric-constant particles with a relative permittivity of 10 or more and a base oil (see, for example, Patent Document 1).

A semiconductor device is also known (see, for example, Patent Document 2) that includes: a semiconductor module section; an insulating resin layer that is bonded to the semiconductor module section and contains a first resin; a frame member that contains a porous body and is arranged so as to surround the insulating resin layer; and a heat sink that, together with the semiconductor module section, sandwiches the insulating resin layer and the frame member, wherein the frame member is compressed while being sandwiched between the semiconductor module section and the heat sink, the insulating resin layer is filled in the region enclosed by the semiconductor module section, the heat sink, and the frame member, and the first resin has permeated into the pores of the porous body.
Patent Document 1: Japanese Unexamined Patent Publication No. 2019-041013
Patent Document 2: International Publication No. WO2021/019614

### SUMMARY OF THE INVENTION

### Problem to be Solved by the Invention

In the invention disclosed in Patent Document 1, a semiconductor module and a cooling apparatus are fixed by screws, and a thermal compound is filled between the semiconductor module and the cooling apparatus to form a semiconductor device. Further miniaturization of semiconductor devices is demanded, and a configuration that eliminates screw-based fixation of the cooling apparatus is desired. However, in such a configuration, a flowable thermal compound may sometimes be unsuitable for a cooling structure.

In addition, in the invention disclosed in Patent Document 2, it is essential to surround the insulating resin layer with a frame member. Furthermore, the relative permittivity has not been taken into consideration, so that if the relative permittivity of the insulating resin layer is small, then when a voltage is applied to operate the semiconductor module, there is a risk that the voltage-resistance property will deteriorate, causing discharge.

### Means for Solving the Problem

As a result of intensive study, the present inventor arrived at use of a resin layer containing particles of high relative permittivity as an adhesive layer between a semiconductor module and a cooling apparatus; thus, the present invention has been completed.

That is, according to one embodiment of the present invention, there is provided a semiconductor device including: a semiconductor module that includes a laminated substrate in which conductive plates are arranged on both sides of an insulating substrate having relative permittivity ε₀, a semiconductor element mounted on the laminated substrate, and an encapsulant that seals and insulates the laminated substrate and the semiconductor element; an adhesive layer containing an epoxy resin and a filler that includes first particles having relative permittivity ε₁ exceeding 10; and a cooling apparatus disposed on the semiconductor module via the adhesive layer, wherein ε₀<ε₁.

In the semiconductor device, it is preferable that ε₁ be 30 or more.

In the semiconductor device, it is preferable that the filler further contain second particles having relative permittivity ε₂ of 10 or less and having thermal conductivity λ₂ of 10 or more.

In the semiconductor device, it is preferable that the second particles be oxide particles.

In the semiconductor device, it is preferable that the content of the first particles be 30 to 80% by mass relative to the total mass of the adhesive layer. Here, the total mass of the adhesive layer refers to the total mass of all components constituting the adhesive layer, which include the epoxy resin, the filler, and optional components. The epoxy resin may include an epoxy resin main agent as well as, optionally, a curing agent, a curing accelerator, an additive, etc.

In the semiconductor device in which the adhesive layer contains second particles, it is preferable that the content of the second particles be 6 to 64% by mass relative to the total mass of the adhesive layer.

In the semiconductor device in which the adhesive layer contains second particles, it is preferable that the content of the first particles be 20 to 80% by mass relative to the total mass of the first and second particles.

In the semiconductor device, it is preferable that the first particles be one or more types of inorganic particles selected from barium titanate, titanium (IV) oxide, and zirconia.

In the semiconductor device in which the adhesive layer contains second particles, it is preferable that the second particles be alumina.

In the semiconductor device, it is preferable that the adhesive layer be formed at a thickness of 20 μm or more and 300 μm or less.

According to another aspect of the present invention, there is provided a cooling structure for use in adhesion to a semiconductor module, comprising: an adhesive layer containing an epoxy resin and a filler that includes first particles having relative permittivity ε₁ exceeding 10; and a cooling apparatus adhered to one surface of the adhesive layer, wherein the semiconductor module includes a laminated substrate in which conductive plates are arranged on both sides of an insulating substrate with relative permittivity ε₀, and ε₀<ε₁.

### Effects of the Invention

According to the present invention, it is possible to provide a miniaturized semiconductor device that does not require screw-fastened parts and that suppresses the potential difference between the conductive plate on the back surface of the semiconductor module and the cooling apparatus, whereby malfunction of the drive circuit due to discharge is avoided, achieving excellent voltage-resistance property and high reliability.

### BRIEF DESCRIPTION OF THE DRAWINGS

FIG. 1 is a conceptual diagram showing a cross-sectional structure of a semiconductor device according to the present invention.

### DESCRIPTION OF PREFERRED EMBODIMENTS

Hereinafter, embodiments of the present invention will be described with reference to the drawings. However, the present invention is not limited to these embodiments.

According to one embodiment of the present invention, there is provided a semiconductor device that includes the following (a), (b), and (c):
(a) a semiconductor module that includes a laminated substrate in which conductive plates are arranged on both sides of an insulating substrate having relative permittivity ε₀, a semiconductor element mounted on the laminated substrate, and an encapsulant that seals and insulates the laminated substrate and the semiconductor element;
(b) an adhesive layer containing an epoxy resin and a filler that includes first particles having relative permittivity ε₁ exceeding 10;
(c) a cooling apparatus disposed on the semiconductor module via the adhesive layer; and
in this semiconductor device, ε₀<ε₁.

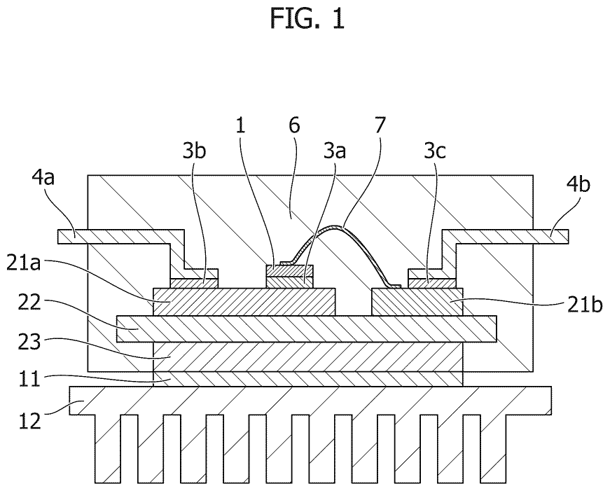

FIG. 1 is a conceptual diagram showing an example of a semiconductor device according to one embodiment of the present invention. In FIG. 1, the semiconductor element 1 is mounted on a second conductive plate 21a, which is part of the laminated substrate 2, via a bonding layer 3a such as solder. A terminal 4a is attached to the second conductive plate 21a via a bonding layer 3b. Also, a terminal 4b is attached to another second conductive plate 21b, which is part of the laminated substrate 2, via a bonding layer 3c. A wiring member 7 such as bonding wire is attached to the top surface of the semiconductor element 1 and to the second conductive plate 21b, whereby the top surface of the semiconductor element 1 is electrically connected to the second conductive plate 21b. These members are encapsulated with an encapsulant 6.

As above, a member obtained by encapsulating, with the encapsulant 6, a member to be encapsulated containing at least the laminated substrate 2 on which the semiconductor element 1 is mounted is referred to as the semiconductor module 10. The semiconductor module 10 is mainly used for power conversion applications and may be called a power semiconductor module. In the illustrated embodiment, there is no heat-dissipating base provided on the back side of the laminated substrate 2 of the semiconductor module 10, i.e., the side opposite to where the semiconductor element 1 is mounted. Furthermore, in FIG. 1, there is not provided any casing for accommodating the semiconductor element or the like and holding the encapsulant 6. However, a casing may be provided for suitably arranging terminals. The semiconductor module 10 and the cooling apparatus 12 are arranged via the adhesive layer 11, and there are no screws or similar fasteners. Note that in this specification, the terms, top surface and bottom surface, are relative terms referring to the top and bottom in the figure for explanatory purposes; these terms are not meant to limit orientation in relation to the usage modes or the like of the semiconductor device when used. Also, in this specification throughout, a member that includes the semiconductor element 1 and the laminated substrate 2 and is sealed and insulated with the encapsulant in an ordinary encapsulation mode is referred to as the member to be encapsulated. In the illustrated embodiment, the member to be encapsulated includes the semiconductor element 1, the laminated substrate 2, the bonding layers 3a, 3b, 3c, the terminals 4a, 4b, and the wiring member 7. If the semiconductor device has a metal heat-dissipating base, the semiconductor module 10 and the heat-dissipating base are bonded by a thermally conductive bonding material such as solder material or a silver sintered body to form a bonded assembly. The bonded assembly, in turn, is arranged on the cooling apparatus via the adhesive layer 11. In that case as well, for the sake of miniaturizing the module, it is preferable that no screws or similar fasteners exist to secure the cooling apparatus to the bonded assembly.

The semiconductor element 1 may be a power chip such as an IGBT or diode chip, and various devices can be used, such as Si devices, SiC devices, or GaN devices. These devices may also be used in combination. For example, a hybrid module that uses an Si-IGBT and an SiC-SBD can be employed. The number of semiconductor elements 1 mounted is not limited to the configuration shown in the figure, and multiple elements may be mounted.

The laminated substrate 2 includes an insulating substrate 22 as well as second conductive plates 21a, 21b formed on one side thereof, and a first conductive plate 23 formed on the other side. As the insulating substrate 22, a material with excellent electrical insulation and thermal conductivity can be used. Example materials of the insulating substrate 22 include inorganic materials such as Al₂O₃, AlN, and SiN, and resins such as epoxy resin, polyimide resin, and liquid crystal polymer. The material of the insulating substrate 22 can be selected such that its relative permittivity ε₀ is less than the relative permittivity ε₁ of the first particles included in the adhesive layer, described later. The relative permittivity ε₀ of the insulating substrate 22 is the relative permittivity so of the material itself: approximately 10 for Al₂O₃; approximately 8 for AlN and SiN; and approximately 4 to 5 for resins.

The second conductive plates 21a, 21b and the first conductive plate 23 can be formed of metal materials such as Cu or Al, which are excellent in workability. In this specification, the first conductive plate 23 composed of Cu may be referred to as a back-surface copper foil. The first conductive plate 23 may be composed of Cu or Al that has been subjected to Ni plating or similar treatment for rust prevention or other purposes. Methods for arranging the second conductive plates 21a, 21b and the first conductive plate 23 on the insulating substrate 22 include direct copper bonding and active metal brazing.

The bonding layers 3a, 3b, 3c can be formed using lead-free solder. Examples of the lead-free solder include, but are not limited to, Sn—Ag—Cu-based, Sn—Sb-based, Sn—Sb—Ag-based, Sn—Cu-based, Sn—Sb—Ag—Cu-based, Sn—Cu—Ni-based, or Sn—Ag-based solder.

In this embodiment, the member to be encapsulated that contains the semiconductor element 1, the laminated substrate 2, the bonding layers 3a, 3b, 3c, the terminals 4a, 4b, and the wiring member 7 as well as, optionally, other terminals (not shown) is sealed and insulated by the encapsulant 6. As the encapsulant 6, a thermosetting resin-based encapsulant or silicone gel may be used. In the illustrated embodiment, using a resin encapsulant that does not require a casing or the like is preferable. In another embodiment, the thermosetting resin-based encapsulant is, for example, preferably an epoxy resin, a maleimide resin, a cyanate resin, or a mixture thereof; in particular, including an epoxy resin is preferable. In its most preferable form, the encapsulant 6 can be formed of an epoxy resin composition that includes an epoxy resin main agent and a curing agent, and optionally an inorganic filler or other additives. The epoxy resin main agent may be an aliphatic epoxy or an alicyclic epoxy.

The term aliphatic epoxy refers to an epoxy compound in which the carbon atom directly bonded to the epoxy group is a carbon that constitutes an aliphatic hydrocarbon. Therefore, even compounds in which main skeleton includes an aromatic ring are classified as aliphatic epoxies if they satisfy the above condition. Examples of aliphatic epoxy resin include, but are not limited to, bisphenol A-type epoxy, bisphenol F-type epoxy, bisphenol AD-type epoxy, biphenyl-type epoxy, cresol novolak-type epoxy, and polyfunctional epoxy with three or more functional groups. They can be used alone or as a mixture of two or more types.

The term alicyclic epoxy resin refers to an epoxy compound in which the two carbon atoms forming the epoxy group constitute an alicyclic compound. Examples of alicyclic epoxy resin include, but are not limited to, mono-functional epoxy, difunctional epoxy, and polyfunctional epoxy having three or more functional groups. They can be used alone or as a mixture of two or more types of alicyclic epoxy resins.

A mixture of an aliphatic epoxy and an alicyclic epoxy may also be used, and the mixing ratio in that case may be as desired; for example, a ratio ranging from 1:4 to 4:1 can be employed, preferably from 1:1 to 1:4, although it is not restricted to any specific ratio.

As the curing agent, there is no particular limitation so long as it can react with the epoxy resin main agent and cure it; however, it is preferable to use an acid anhydride-based curing agent. Examples of acid anhydride-based curing agents include aromatic acid anhydrides, specifically such as phthalic anhydride, pyromellitic anhydride, and trimellitic anhydride. Alternatively, the examples include alicyclic acid anhydrides, specifically such as tetrahydrophthalic anhydride, methyl tetrahydrophthalic anhydride, hexahydrophthalic anhydride, methyl hexahydrophthalic anhydride, and methyl nadic anhydride; or aliphatic acid anhydrides, specifically such as succinic anhydride, polyadipic anhydride, polysebacic anhydride, and polyazelaic anhydride. It is preferable that the amount of the curing agent blended be 50 parts by mass or more and 170 parts by mass or less, relative to 100 parts by mass of the epoxy resin main agent; more preferably, 80 parts by mass or more and 150 parts by mass or less. If the amount of the curing agent blended is less than 50 parts by mass, incomplete crosslinking may cause the glass transition temperature to decrease; if it is more than 170 parts by mass, moisture resistance, high heat distortion temperature, and thermal stability may deteriorate.

A curing accelerator may be further added as an optional component to the epoxy resin composition. Examples of curing accelerators include imidazole or derivatives thereof, tertiary amines, borate esters, Lewis acids, organometallic compounds, and metal salts of organic acids; the amount thereof may be appropriately adjusted. The amount of the curing accelerator added is preferably 0.01 parts by mass or more and 50 parts by mass or less, and more preferably 0.1 parts by mass or more and 20 parts by mass or less, relative to 100 parts by mass of the epoxy resin main agent.

Examples of the inorganic filler that may be included as an optional component in the epoxy resin composition include, but are not limited to, fused silica, silica, alumina, aluminum hydroxide, titania, zirconia, aluminum nitride, talc, clay, mica, and glass fibers. These inorganic fillers help to increase the thermal conductivity of the cured product and reduce its thermal expansion. These inorganic fillers may be used alone or in a mixture of two or more types. These inorganic fillers may be microfillers or nanofillers; and it is also possible to use two or more inorganic fillers with different particle sizes and/or types. In particular, an inorganic filler with an average particle size of about 0.2 μm or more and 20 μm or less is preferably used. The amount of the inorganic filler added is preferably 100 parts by mass or more and 600 parts by mass or less, and more preferably 200 parts by mass or more and 400 parts by mass or less, when the total mass of the epoxy resin main agent and curing agent is taken as 100 parts by mass. If the amount of the inorganic filler blended is less than 100 parts by mass, the thermal expansion coefficient of the encapsulant becomes high, which may cause delamination or cracking to easily occur. If the amount blended is more than 600 parts by mass, the viscosity of the composition increases, resulting in poor extrudability.

The epoxy resin composition may also contain, within a range that does not impair its properties, any optional additive. Examples of the additives include, but are not limited to, flame retardants, pigments for coloring the resin, and plasticizers and silicone elastomers for enhancing crack resistance. The type and amount of such optional additives can be suitably determined by those skilled in the art according to the specifications required for the semiconductor device and/or encapsulant.

A semiconductor module 10 having no heat-dissipating base, as illustrated, can be manufactured by placing the member to be encapsulated in an appropriate mold, filling the mold with the encapsulant 6, and performing heat curing. Examples of molding methods for forming such an encapsulated body include vacuum casting, transfer molding, and liquid transfer molding, but there is no limitation to a specific molding method. Using such a molding method, one can produce a semiconductor module 10 in which the first conductive plate 23 (back-surface copper foil) on one side of the member to be encapsulated and any necessary external terminals are exposed, while other members are sealed and insulated by the encapsulant 6.

The adhesive layer 11 is made of a composition containing an epoxy resin and a filler containing first particles having relative permittivity ε₁ exceeding 10. The adhesive layer 11 bonds the semiconductor module 10 and the cooling apparatus 12, functioning as a heat-dissipating layer for heat generated by the semiconductor module 10. Regarding the properties of the adhesive layer 11, the glass transition temperature thereof need not be as high as that of the encapsulant; however, it is preferable that the glass transition temperature thereof be at least 125° C.

The adhesive layer 11 can be applied, for example, in a thickness of about 20 μm or more and 300 μm or less to the back surface of the semiconductor module 10, which includes the first conductive plate 23 exposed from the encapsulant 6. More preferably, the thickness of the adhesive layer 11 is 50 μm or more and 150 μm or less; this thickness range is advantageous in view of electrostatic capacitance. The adhesive layer 11 is also required to be electrically insulating. If it were electrically conductive, the material, once separated into discrete pieces, could cause short circuits. Therefore, it is preferable it not include conductive materials.

Next, details of the composition constituting the adhesive layer 11 will be explained. The adhesive layer 11 contains an epoxy resin and a filler. The term “epoxy resin” here means a concept that includes an epoxy resin main agent as an essential component, and optionally a curing agent, curing accelerator, or additive. The epoxy resin main agent may be selected from the same options as those for the encapsulant. Preferably, as the main agent, an aliphatic epoxy resin system with both insulating and excellent adhesive properties is chosen, and examples thereof include, but are not limited to, a bisphenol A-type epoxy, a bisphenol F-type epoxy, a biphenyl-type epoxy, or a cresol novolak-type epoxy. They can be used alone or as a mixture of two or more types. Optionally, an epoxy resin other than an aliphatic epoxy resin may be mixed with the aliphatic epoxy resin. In that case, it is preferable that the aliphatic epoxy resin constitute 60% by mass or more, and more preferably 80% by mass or more, of the main agent. Epoxy resins other than the aliphatic epoxy resins that may be mixed include, but are not limited to, alicyclic epoxy resins.

A curing agent may be included as an optional component in the epoxy resin. As for the curing agent, there is no particular limitation so long as it reacts with the epoxy resin main agent and cures it; preferably, a phenol-based curing agent or an amine-based curing agent is used due to good adhesion to the first conductive plate or heat-dissipating base. Specific usable examples thereof include, but are not limited to, phenol novolak resin, multi-aromatic novolak resin, polyamide polyamine, aliphatic polyamine, and aromatic polyamine. To the epoxy resin, a curing accelerator may be further added as an optional component. As the curing accelerator, imidazole or the like can be used.

In this embodiment, the filler in the composition constituting the adhesive layer 11 includes first particles as an essential component. The first particles have a relative permittivity ε₁ greater than that of the insulating substrate 22, ε₀, with the value of that relative permittivity exceeding 10. In this specification, particles with a relative permittivity value exceeding 10 are referred to as high-dielectric-constant particles. The high-dielectric-constant particles may be organic or inorganic, provided that in the adhesive layer 11 they maintain a particulate form and do not chemically react with the epoxy resin.

Examples of organic particles usable as high-dielectric-constant particles include, but are not limited to, powdered polyvinylidene fluoride (PVDF particles, relative permittivity εᵣ=13). Since PVDF particles have a high relative permittivity and good heat resistance, those particles are preferred as a filler that is dispersed in the adhesive layer 11 while maintaining the original particle form thereof prior to addition.

Examples of inorganic particles usable as high-dielectric-constant particles include barium titanate (BaTiO₃, relative permittivity εᵣ=1450), strontium titanate (SrTiO₃, relative permittivity ε=330), lithium titanate (Li₂TiO₃, relative permittivity εᵣ=40), and lead titanate (PbTiO₃, relative permittivity εᵣ=250). Those inorganic particles have a perovskite crystal structure expressed by a compositional formula ABO₃, where examples of elements serving as the element A include Ba, Pb, and La, and examples of elements serving as the element B include Ti and Zr, but the present invention is not limited thereto. Examples also include lead zirconate titanate (PZT, Pb(Zr,Ti) O₃, relative permittivity εᵣ=1300 to 2100), lead niobate (PbNb₂O₆, εᵣ=370), hafnium (IV) oxide (HfO₂, relative permittivity εᵣ=15), tantalum pentoxide (Ta₂O₅, relative permittivity εᵣ=22), titanium (IV) oxide (TiO₂, relative permittivity εᵣ=48 for anatase-type TiO₂), zirconium oxide (ZrO₂, relative permittivity εᵣ=33), yttria (Y₂O₃, relative permittivity εᵣ=11), chromium oxide (Cr₂O₃, relative permittivity ε=13.3), copper oxide (CuO, relative permittivity εᵣ=18.1), nickel oxide (NiO, relative permittivity εᵣ=11.9), lithium niobate (LiNbO₃, relative permittivity εᵣ=29), silicon (Si, relative permittivity ε=12), barium magnesium niobate (Ba(Mg_{1/3}Nb_{2/3}) O₃, relative permittivity ε=25), barium neodymium titanate (Ba₃Nd_{9.3}Ti₁₈O₅₄, relative permittivity ¿r=85), and diamond (relative permittivity εᵣ=26). One or more inorganic particles selected from among those examples can be included in the filler of the present embodiment, but the present invention is not limited thereto.

The first particle may be a mixture of several different types of high-dielectric-constant particles. In that case as well, the relative permittivity ε₁ of the mixture is only required to be greater than that of the insulating substrate 22, ε₀. To determine the relative permittivity ε₁ of a mixture of several different first particles, one can measure the relative permittivity of a sample containing the mixture using a dielectric constant measurement instrument, then calculate the relative permittivity.

The shape of the first particles is not particularly limited; they may be spherical, needle-shaped, foil-shaped, fibrous, or the like, but spherical particles are particularly preferred. The average particle size of the first particles is, for example, about 1 μm or more and about 50 μm or less; preferably about 1 μm or more and about 10 μm or less; more preferably about 5 μm or more and about 10 μm or less. The particle size of the first particles is determined in relation to the layer thickness of the adhesive layer 11; preferably, the particle size is smaller than that thickness.

It is preferable that the filler be contained at 30 to 80% by mass when the total mass of the resin composition constituting the adhesive layer 11 is taken as 100%, where the first particles may account for 100% thereof. Here, the resin composition constituting the adhesive layer 11 refers to a composition containing the epoxy resin defined above and the filler, and optionally any other component, encompassing all components that constitute adhesive layer 11. By having the adhesive layer 11 contain the first particles in this range, one can increase the electrostatic capacitance of the adhesive layer 11 and reduce the voltage applied to the insulating substrate in the semiconductor module. The first particles are more preferably contained at 60 to 80% by mass when the total mass of the resin composition is taken as 100%. By incorporating a relatively large proportion of the first particle having a high relative permittivity, the electrostatic capacitance of adhesive layer 11 can be further increased, and dielectric breakdown can be suppressed.

In addition to the first particles, the filler may optionally include second particles. The second particles have a thermal conductivity λ₂ of 10 W/(m·K) or more and a relative permittivity ε₂ of 10 or less. Examples of second particles include, but are not limited to, alumina (Al₂O₃, ε₂=10, λ₂=20), aluminum nitride (AlN, ε₂=8, λ₂=180), and boron nitride (BN, ε₂=4, λ₂=50). By including these second particles with high thermal conductivity, the heat dissipation characteristics of the adhesive layer 11 can be improved. The second particles may also be a mixture of two or more different types. The shape and particle size of the second particles may be chosen within the same range as those explained for the first particles. Therefore, the shape of the second particles can be the same as or different from that of the first particles, and the particle size of the second particles can be the same as or different from that of the first particles.

It is more preferable that the second particles be oxide particles; in some embodiments, it may be preferable not to include nitride particles. This is because nitride particles have partial discharge inception voltage somewhat lower than that of oxide particles.

The content of the second particles may be 6 to 64% by mass when the total mass of the resin composition constituting the adhesive layer 11 is taken as 100%. Additionally, it is preferable that the content of the second particles be 20 to 80% by mass when the total mass of the first and second particles is taken as 100%. However, the total mass of the first particles and the second particles is within a preferred range as the filler content, and is preferably 30 to 80% by mass when the total mass of the resin composition is taken as 100%.

Note that in some cases, the filler may contain particles that do not qualify as either first or second particles.

The resin composition constituting the adhesive layer 11 may optionally contain a silane coupling agent in addition to the epoxy resin and filler. A silane coupling agent may be preferred because it can improve the adhesion between the epoxy resin and the filler and contribute to suppressing dielectric breakdown of the adhesive layer 11. The type of silane coupling agent may vary depending on the type of epoxy resin included in the adhesive layer 11, as well as the types of the first particles and, optionally, the second particles; for example, a trialkoxy-type silane coupling agent can be used. The content of the silane coupling agent can be 0.1 to 5% by mass, and preferably 1 to 3% by mass, when the total mass of the resin composition constituting the adhesive layer 11 is taken as 100%.

The composition constituting the adhesive layer 11 may contain any optional additive that does not impair its properties. Examples of the additives include, but are not limited to, antioxidants or modifiers. It is preferable that the adhesive layer 11 be insulating; it is preferable not to include conductive materials such as metal particles. This is because if the adhesive layer 11 were to scatter, there could be a risk of short-circuiting wiring or the like in the semiconductor device. Furthermore, to lower the elastic modulus of the adhesive layer, one may add nylon, nitrile rubber (also referred to as NBR rubber, a copolymer of acrylonitrile and butadiene), acrylic resin, etc. This allows the adhesive layer to have higher rigidity and strength and reduce delamination. In that case, the amount added is preferably about 1 to 10% by mass relative to the total mass of the epoxy resin.

The adhesive layer 11 can be prepared by mixing the filler, which includes the first particles, and optionally, the second particles, with an epoxy resin and preferably dispersing it uniformly, and then applying it onto the back surface of the first conductive plate 23 of the semiconductor module. When adhering it to the cooling apparatus 12, the adhesive layer 11 may be cured by heating or allowed to cure naturally without heating.

As the cooling apparatus 12, one can use a member with good thermal conductivity and having electrical conductivity. For example, a metal member such as Cu or Al can be used; when further weight reduction is required, Al is preferable. A cooling apparatus 12 made of Al material may be subjected to Ni plating, Cr plating, or the like as needed, so that at least the portion contacting the adhesive layer 11 can be made conductive. The shape and specifications of the cooling apparatus 12 can be selected as desired to suit the intended use or the like of the semiconductor module, and are not limited to a particular type. In other words, the cooling apparatus may be plate-shaped or may include an air-cooling mechanism such as fins or a water-cooling mechanism.

With the semiconductor device according to the present embodiment, providing an adhesive layer 11 containing high-dielectric-constant particles and having a high relative permittivity makes it possible to reduce the potential difference between the cooling apparatus 12 and the first conductive plate 23 of the semiconductor module 10, suppress partial discharge, eliminate malfunction of the device's drive circuit, and offer a high-voltage-resistance semiconductor device with high reliability. In particular, by adding particles in which relative permittivity is higher than that of the insulating substrate 22, one can further reduce the potential difference with the first conductive plate 23. That is, partial discharge can be suppressed and heat dissipation can be promoted by bonding the electrically insulated conductive plate and the conductive material such as a cooling apparatus with the high-dielectric adhesive layer 11. Moreover, by replacing the thermal compound with the adhesive layer 11, a small and highly manufacturable semiconductor device can be obtained without any structures or manufacturing steps related to screw fastening.

Note that the present invention is not limited to the type of the illustrated semiconductor module; it covers any semiconductor device in which a conductive plate of the semiconductor module and a cooling apparatus are insulated from each other by an adhesive layer. For example, instead of the wire bonding shown in FIG. 1, a semiconductor module that uses conductive connection members such as copper pins or lead frames, or a semiconductor module that has a printed circuit board connected to the semiconductor element by copper pins inside or outside the encapsulant, may likewise be formed into a semiconductor device of the present invention by placing a cooling apparatus on the surface of the first conductive plate exposed from the encapsulant via the adhesive layer. Alternatively, instead of the semiconductor module without a casing in FIG. 1, one could use a semiconductor module in which a casing made of polyphenylene sulfide (PPS) or the like is fixed to the laminated substrate, and the casing is filled with silicone gel for insulating encapsulation. In that case as well, one can secure the casing in a manner that leaves the surface of the first conductive plate exposed, and place a cooling apparatus on the surface of the first conductive plate via the adhesive layer, obtaining a semiconductor device according to the present invention.

According to another aspect, the present invention relates to a cooling structure for use in adhesion to a semiconductor module. The cooling structure includes:
(A) an adhesive layer containing an epoxy resin and a filler that includes first particles having relative permittivity ε₁ exceeding 10; and
(B) a cooling apparatus adhered to one surface of the adhesive layer, wherein the semiconductor module to be adhered includes a laminated substrate in which conductive plates are arranged on both sides of an insulating substrate with relative permittivity ε₀, and ε₀<ε₁.

The adhesive layer and cooling apparatus constituting the cooling structure may be the same as the adhesive layer 11 and cooling apparatus 12 described above with reference to FIG. 1. The semiconductor module to be adhered may also have the same configuration as the semiconductor module 10 described above with reference to FIG. 1, and include a semiconductor element constituting the semiconductor module and a laminated substrate having an insulating substrate.

The cooling structure can be maintained with the adhesive layer provided on the cooling apparatus, and can be adhered to the semiconductor module in manufacturing the semiconductor device. An advantage of the cooling structure is that it can be managed as a separate process from the semiconductor module and can be applied regardless of the type of semiconductor module.

### Examples

Examples of the present invention are described below in detail. However, the present invention is not limited to the scope of the following examples.

Power semiconductor devices were fabricated in the examples and comparative examples. For the laminated substrate, an alumina substrate (manufactured by Rogers) with Cu conductive plates having a thickness of 0.3 mm and an insulating substrate having a thickness of 0.38 mm was used. The material of the insulating substrate was Δl₂O₃. A solder and an Si power semiconductor element, a solder and copper pins, and a printed circuit board were placed on the laminated substrate and bonded by soldering in an N₂ reflow furnace to obtain the member to be encapsulated. Next, this member to be encapsulated was set in a mold. As the encapsulant, a mixture (mass ratio 10:5:50) of the following was used:
Aliphatic epoxy resin main agent: jER630 (Mitsubishi Chemical Corporation)
Curing agent: jER Cure 113 (Mitsubishi Chemical Corporation)
Inorganic filler (silica): EXCELICA(TM) with an average particle diameter of several micrometers to a few tens of micrometers (Tokuyama Corporation).

This encapsulant was vacuum-degassed and injected into the mold. Primary curing was performed at 100° C. for 1 hour, followed by secondary curing at 150° C. for 3 hours, yielding a power semiconductor module.

To form the adhesive layer, barium titanate (BaTiO₃) particles (relative permittivity ε₁=1450, average particle size 5 μm) as first particles were mixed into an epoxy resin containing a predetermined amount of alumina (Al₂O₃) as second particles. The composition of the epoxy resin was as follows in a mass ratio of 10:5:1:0.1:
Main agent: Bisphenol A-type epoxy
Curing agent: Phenol novolak curing agent
Additive: Acrylic resin
Curing accelerator: Imidazole

The total content of alumina plus barium titanate was 80% by mass when the total mass of the adhesive layer was taken as 100%. This mixture was uniformly dispersed to obtain a resin composition for the adhesive layer. A coating of about 100 μm thickness of this adhesive layer was applied to the exposed conductive plate surface of the laminated substrate of the power semiconductor module, bonded to an aluminum cooling apparatus, and heat-cured at 150° C. for 1 hour, yielding the semiconductor device of Example 1.

By changing the compound type of the first particles and the content of the first and second particles as shown in Table 1, semiconductor devices of Examples 2 to 5 were obtained. By changing the second particles to aluminum nitride (AlN) and adjusting the content of the first and second particles as shown in Table 1, semiconductor devices of Examples 6 and 7 were obtained. Without using the second particles, by changing the compound type and content of the first particles as shown in Table 1, semiconductor devices of Examples 8 to 11 were obtained. On the other hand, by omitting the first particles and using the compound types and contents of the second particles as shown in Table 2, semiconductor devices of Comparative Examples 1 to 5 were obtained.

In Tables 1 and 2, “Filler Content (%)” refers to the % by mass of the filler in the resin composition constituting the adhesive layer, i.e., when the total mass of the epoxy resin main agent, curing agent, curing accelerator, additive, and filler is taken as 100%; “First Particles Content (%)” refers to the % by mass of the first particles when the total mass of the resin composition constituting the adhesive layer is taken as 100%; “Ratio in Filler (%)” refers to the % by mass of the first particles when the total mass of the filler is taken as 100%; “Second Particles Content (%)” refers to the % by mass of the second particles when the total mass of the resin composition constituting the adhesive layer is taken as 100%. Note that ε₀ is the relative permittivity of the insulating substrate, ε₁ is the relative permittivity of the first particles, ε₂ is the relative permittivity of the second particles, λ₁ is the thermal conductivity of the first particles, and λ₂ is the thermal conductivity of the second particles.

### Partial Discharge Evaluation

For the semiconductor devices of Examples 1 to 11 and Comparative Examples 1 to 5, partial discharge properties before and after moisture absorption were evaluated using a partial discharge detector (evaluation of voltage-resistance property). “Before Moisture Absorption” refers to the semiconductor device immediately after manufacture. “After Moisture Absorption” refers to the semiconductor device after being left for 300 hours under conditions of 85° C. and 85% relative humidity. The partial discharge was evaluated by gradually applying the supply voltage up to 2.5 kV and defining the voltage at which a signal of 10 pC or more was detected as the partial discharge inception voltage. If the supply voltage reached 2.5 kV, and the discharge charge amount after 60 seconds was less than 10 pC, it was considered that no partial discharge occurred. Table 1 and Table 2 show the partial discharge inception voltages. In cases in which no partial discharge was observed, the partial discharge inception voltage was greater than 2.5 kV, and in cases in which partial discharge was observed, the corresponding voltage is shown.

### Power Cycling Test Evaluation

A ΔTc power cycling (P/C) test was conducted on the semiconductor devices after moisture absorption. The post-moisture-absorption P/C test can evaluate the reliability of the semiconductor device, including heat dissipation. The test condition for casing temperature (Tc) was Δ=80° C. (25° C. to 105° C.). For each of the semiconductor devices in the examples and comparative examples, the thermal resistance Rth (K/W) between the back surface of the first conductive plate 23 and the surface of the heat-dissipating base was measured, and the cycle count at which that thermal resistance Rth (K/W) had risen by 20% from the initial state was evaluated. In Tables 1 and 2, “Post-Moisture-Absorption P/C” values are shown as relative numbers, with the cycle count of Comparative Example 1 (5k cycles) taken as 1. If the post-moisture-absorption P/C cycle count is 1.5 times or more of the reference (Comparative Example 1), then it has been confirmed that the same cycle count can be achieved even if the temperature change A is 100° C.; thus, a relative value of 1.8 times or more in the post-moisture-absorption P/C test is even more preferable.

### Overall Evaluation

Based on both the partial discharge evaluation and the power cycling test evaluation, an overall evaluation was performed for each semiconductor device:
Cases in which the insulation property was satisfactory and heat dissipation was also even better were marked “A”;
Cases in which the insulation property was satisfactory were marked “B”; and
Cases in which the insulation property was problematic were marked “C.”

TABLE 1

| | | Example | | | | | | | | | | |
|---|---|---|---|---|---|---|---|---|---|---|---|---|
| | | 1 | 2 | 3 | 4 | 5 | 6 | 7 | 8 | 9 | 10 | 11 |
| Insulating Substrate (Thickness of 380 μm) | | Al₂O₃ | ← | ← | ← | ← | ← | ← | ← | ← | ← | ← |
| | ε₀ | 10 | ← | ← | ← | ← | ← | ← | ← | ← | ← | ← |
| Adhesive Layer | Resin | Epoxy | ← | ← | ← | ← | ← | ← | ← | ← | ← | ← |
| | Filler Content (%) | 80 | ← | ← | ← | ← | ← | ← | ← | ← | ← | 30 |
| | First Particle | BaTiO₃ | TiO₂ | ZrO₂ | ← | ← | BaTiO₃ | ZrO₂ | BaTiO₃ | ZrO₂ | TiO₂ | BaTiO₃ |
| | ε₁ | 1450 | 48 | 33 | 33 | 33 | 1450 | 33 | 1450 | 33 | 48 | 1450 |
| | λ₁ | 6 | 10 | 6.2 | 6.2 | 6.2 | 6 | 6.2 | 6 | 6.2 | 10 | 6 |
| | First Particle Content (%) | 40 | 40 | 40 | 16 | 64 | 40 | 40 | 80 | 80 | 80 | 30 |
| | Ratio in Filler (%) | 50 | 50 | 50 | 20 | 80 | 50 | 50 | 100 | 100 | 100 | 100 |
| | Second Particle | Al₂O₃ | ← | ← | ← | ← | AlN | ← | None | None | None | None |
| | ε₂ | 10 | ← | ← | ← | ← | 8 | ← | — | — | — | — |
| | λ₂ | 20 | ← | ← | ← | ← | 180 | ← | — | — | — | — |
| | Second Particle Content (%) | 40 | ← | ← | 64 | 16 | 40 | ← | — | — | — | — |
| Evaluation | Partial Discharge Occurrence | >2.5 | >2.5 | >2.5 | >2.5 | >2.5 | >2.5 | >2.5 | >2.5 | >2.5 | >2.5 | >2.5 |
| | Voltage (kV) (Before Moisture | | | | | | | | | | | |
| | Absorption) | | | | | | | | | | | |
| | Partial Discharge Occurrence | >2.5 | >2.5 | >2.5 | >2.5 | >2.5 | 2 | 2 | >2.5 | >2.5 | >2.5 | >2.5 |
| | Voltage (kV) (After Moisture | | | | | | | | | | | |
| | Absorption) | | | | | | | | | | | |
| | Post-Moisture-Absorption P/C | 1.8 | 1.8 | 1.8 | 1.8 | 1.5 | 1.5 | 1.5 | 1.2 | 1.2 | 1.2 | 1 |

| | | | | | | | | | | | |
|---|---|---|---|---|---|---|---|---|---|---|---|
| Overall Evaluation | A | A | A | A | B | B | B | B | B | B | B |

TABLE 2

| | | Comparative Example | | | | |
|---|---|---|---|---|---|---|
| | | 1 | 2 | 3 | 4 | 5 |
| Insulating Substrate | | Al₂O₃ | | | | |
| (Thickness of 380 μm) | | Substrate | | | | |
| | ε₀ | 10 | ← | ← | ← | ← |
| Adhesive Layer | Resin | Epoxy | ← | ← | ← | ← |
| | Filler Content (%) | 80 | ← | ← | ← | 30 |
| | First Particle | — | — | — | — | — |
| | ε₁ | — | — | — | — | — |
| | λ₁ | — | — | — | — | — |
| | First Particle | — | — | — | — | — |
| | Content (%) | | | | | |
| | Ratio in Filler (%) | 0 | 0 | 0 | 0 | 0 |
| | Second Particle | SiO₂ | Al₂O₃ | AlN | BN | Al₂O₃ |
| | ε₂ | 4 | 10 | 8 | 4 | 10 |
| | λ₂ | 2 | 20 | 180 | 50 | 20 |
| | Second Particle | 80 | ← | ← | ← | 30 |
| | Content (%) | | | | | |
| Evaluation | Partial Discharge | 1.2 | 1.2 | 1.2 | 1.2 | 1.2 |
| | Occurrence Voltage (kV) | | | | | |
| | (Before Moisture | | | | | |
| | Absorption) | | | | | |
| | Partial Discharge | 1.2 | 1.2 | 0.8 | 0.8 | 0.8 |
| | Occurrence Voltage (kV) | | | | | |
| | (After Moisture | | | | | |
| | Absorption) | | | | | |
| | Post-Moisture- | Reference | 2 | 1.5 | 1.5 | 1.1 |
| | Absorption P/C | 1(5k cycles) | | | | |

| | | | | | |
|---|---|---|---|---|---|
| Overall Evaluation | C | C | C | C | C |

From Tables 1 and 2, it is confirmed that using an adhesive layer containing at least first particles can prevent partial discharge not only before moisture absorption but also after moisture absorption, and that sufficient reliability can be obtained in the power cycling test after moisture absorption. It has at least been confirmed that if the thermal conductivity 21 of the first particles is 6 or more, heat dissipation can be enhanced. Additionally, comparing Examples 1 to 7 with Examples 8 to 11 confirms that, if the adhesive layer contains second particles with high thermal conductivity that is oxide-based in addition to the first particles, the P/C endurance in the power cycling test after moisture absorption is higher, and the result is even more reliable. This is presumably because the second particles contribute to heat dissipation. Specifically, it has been confirmed that when the second particles are added, the voltage-resistance characteristics are slightly better when Al₂O₃ is used as the second particles than when AlN is used (Examples 6 and 7). This is presumably because the adhesion between a nitride such as AlN and the resin of the adhesive layer is slightly inferior to that of an oxide. Hence, oxide-type second particles are more preferable than nitride-types. On the other hand, as shown in Comparative Examples 1 to 5, using only a filler with ε₂ less than 10 results in low voltage-resistance characteristics. If the rated voltage is 1.2 kV or more, in the modules of Comparative Examples 1 to 5, discharge will occur during operation, potentially leading to dielectric breakdown and module destruction.

Without being bound by theory, the results of the examples suggest that bringing the relative permittivities of the ceramic in the insulating substrate and the adhesive layer closer together increases the electrostatic capacitance and lowers the voltage share across the adhesive layer, thereby preventing discharge. In the comparative examples, a large difference between the relative permittivities of the ceramic insulating substrate and the adhesive layer is presumably why discharge occurred starting at 1.2 kV with discharge levels of 10 pC or more.

The examples of the present invention confirm that by using an adhesive layer mixed with high-dielectric-constant particles, partial discharge can be suppressed in the semiconductor device; moreover, adding high-thermal-conductivity particles can maintain heat dissipation. Accordingly, the present invention enables the provision of a highly reliable power semiconductor device.

### REFERENCE SIGNS LIST

1: Semiconductor element
2: Laminated substrate
21: Second conductive plate
22: Insulating substrate
23a, 23b: First conductive plate
3a, 3b, 3c: Bonding layer
6: Encapsulant
10: Semiconductor module
11: Adhesive layer
12: Cooling apparatus

What is claimed is:

1. A semiconductor device comprising:
a semiconductor module that includes
a laminated substrate in which conductive plates are arranged on both sides of an insulating substrate having relative permittivity ε₀,
a semiconductor element mounted on the laminated substrate, and
an encapsulant that seals and insulates the laminated substrate and the semiconductor element;
an adhesive layer containing an epoxy resin and a filler that includes first particles having relative permittivity ε₁ exceeding 10; and
a cooling apparatus disposed on the semiconductor module via the adhesive layer,
wherein ε₀<ε₁.

2. The semiconductor device according to claim 1, wherein ε is 30 or more.

3. The semiconductor device according to claim 1, wherein the filler further includes second particles having relative permittivity ε₂ of 10 or less and having thermal conductivity λ₂ of 10 or more.

4. The semiconductor device according to claim 3, wherein the second particles are oxide particles.

5. The semiconductor device according to claim 1, wherein a content of the first particles is 30 to 80% by mass relative to a total mass of the adhesive layer.

6. The semiconductor device according to claim 3, wherein a content of the second particles is 6 to 64% by mass relative to a total mass of the adhesive layer.

7. The semiconductor device according to claim 3, wherein a content of the first particles is 20 to 80% by mass relative to a total mass of the first and second particles.

8. The semiconductor device according to claim 5, wherein the first particles are one or more types of inorganic particles selected from barium titanate, titanium (IV) oxide, and zirconia.

9. The semiconductor device according to claim 3, wherein the second particles are alumina.

10. The semiconductor device according to claim 1, wherein the adhesive layer is formed at a thickness of 20 μm or more and 300 μm or less.

11. A cooling structure for use in adhesion to a semiconductor module, comprising:
an adhesive layer containing an epoxy resin and a filler that includes first particles having relative permittivity ε₁ exceeding 10; and
a cooling apparatus adhered to one surface of the adhesive layer,
wherein the semiconductor module includes a laminated substrate in which conductive plates are arranged on both sides of an insulating substrate having relative permittivity ε₀, and ε₀<ε₁.
